(19) United States
(12) Patent Application Publication
(10) Pub. No.: US 2026/0040778 A1
(43) Pub. Date: Feb. 5, 2026

(54) DISPLAY PANEL AND DISPLAY DEVICE

(71) Applicant: HKC CORPORATION LIMITED, Shenzhen (CN)

(72) Inventors: YOU LI, Shenzhen (CN); Haijiang Yuan, Shenzhen (CN)

(21) Appl. No.: 19/283,051

(22) Filed: Jul. 28, 2025

(30) Foreign Application Priority Data
Jul. 30, 2024 (CN) 202411034821.7

(51) Int. Cl. H10K 59/13; H10K 59/35; H10K 59/80

(52) U.S. Cl. CPC H10K 59/13; H10K 59/873; H10K 59/353

(57) ABSTRACT

A display panel and a display device are provided. The display panel includes a substrate, a pixel driving layer, a light-emitting unit layer, and a light filtering functional layer. The pixel driving layer is disposed on the substrate. The light-emitting unit layer is disposed on the pixel driving layer. The light filtering functional layer is disposed on the light-emitting unit layer. The light-emitting unit layer includes red light-emitting units, green light-emitting units, and blue light-emitting units. The light filtering functional layer includes sensing structures and light-adjusting layers. The sensing structures are configured to control a light transmittance of the light-adjusting layers disposed on locations of the green light-emitting units and the blue light-emitting units to increase after sensing water and oxygen, so as to reduce a red-light-displaying phenomenon, thereby improving the quality of the display panel.

### CROSS-REFERENCE TO RELATED APPLICATION

The present disclosure claims foreign priority to Chinese Patent Application No. CN202411034821.7, titled “DISPLAY PANEL AND DISPLAY DEVICE”, filed on Jul. 30, 2024 in the China National Intellectual Property Administration, and the entire contents of which are hereby incorporated by reference.

### TECHNICAL FIELD

The present disclosure relates to a field of display technology, and in particular to a display panel and a display device.

### BACKGROUND

Organic light-emitting diodes (OLEDs) have characteristics of surface light sources, emitting cold light, energy saving, fast response, flexibility, ultra-lightness and low cost, and mass production technology thereof is increasingly mature. Since the OLEDs have poor stability and are extremely sensitive to water and oxygen, packaging technology of the OLEDs is particularly critical. The main purpose of packaging of the OLEDs is to prevent water vapor and oxygen from entering the OLEDs. However, cracks are prone to be generated during the production process of an encapsulation layer of the OLEDs. When cracks appear on an OLED display screen, water vapor from the outside enters the OLED display screen, and the aging speed of an organic light-emitting layer device is accelerated. Therefore, the OLEDs must be strictly encapsulated to extend their service life and improve stability.

However, an edge of an OLED display panel is generally the weakest part of the package. After the OLED display panel undergoes reliability verification such as high temperature and high humidity, water and oxygen may enter the edge of the OLED display panel, causing the light transmission wavelength range (the wavelength range of light allowed to pass through) of an insulating layer at the edge to change, thereby causing the edge of the OLED display panel to display red light when displaying.

### SUMMARY

A purpose of the present disclosure is to provide a display panel and a display device, which reduce the red light emitted by the display panel after water and oxygen enter by configuring a light filtering functional layer. Specifically, the present disclosure improves the quality of the display panel by changing a light transmittance of light-adjusting layers thereof after sensing water and oxygen through sensing structures thereof.

The present disclosure provides the display panel. The display panel includes a substrate, a pixel driving layer, a light-emitting unit layer, and a light filtering functional layer. The pixel driving layer is disposed on the substrate. The light-emitting unit layer is disposed on the pixel driving layer. The light filtering functional layer is disposed on the light-emitting unit layer. The light-emitting unit layer includes red light-emitting units, green light-emitting units, and blue light-emitting units. The light filtering functional layer includes sensing structures and light-adjusting layers. The sensing structures are configured to control a light transmittance of the light-adjusting layers disposed on locations of the green light-emitting units and the blue light-emitting units to increase after sensing water and oxygen.

Optionally, the light filtering functional layer further includes a sealing layer. The sealing layer includes sealing cavities. Each of the sealing cavities includes a corresponding one of the sensing structures and a corresponding one of the light-adjusting layers. The sensing structures are configured to sense water and oxygen in the sealing layer. Each of the sensing structures is disposed on one side of a corresponding one of the light-adjusting layers away from the light-emitting unit layer.

Optionally, each of the light-adjusting layers includes an acidic solution and a pH-sensitive hydrogel, the pH-sensitive hydrogel thereof is in the acidic solution thereof, and when a pH value of the acidic solution thereof increases, a light transmittance of the pH-sensitive hydrogel thereof increases accordingly. Each of the sensing structures includes an alkaline metal and an anion exchange membrane, the anion exchange membrane thereof is configured to isolate the alkaline metal thereof and the corresponding one of the light-adjusting layers, and the alkaline metal thereof is configured to absorb water and oxygen and then release alkaline anions to enter a corresponding acidic solution through the anion exchange membrane thereof, so as to improve the pH value of the corresponding acidic solution.

Optionally, each of the sensing structures further includes a gas filter membrane and a liquid filter membrane. A reaction chamber is formed between the gas filter membrane thereof and the liquid filter membrane thereof. The alkaline metal thereof is disposed in the reaction chamber thereof. The gas filter membrane thereof is disposed on one side of the liquid filter membrane thereof away from the corresponding one of the light-adjusting layers. The liquid filter membrane thereof is disposed between the reaction chamber thereof and the anion exchange membrane thereof.

Optionally, in each of the light-adjusting layers, the alkaline metal thereof includes metallic sodium, the metallic sodium absorbs water and oxygen to form a sodium hydroxide solution, and the sodium hydroxide solution releases hydroxide ions into the acidic solution.

Optionally, a thickness of the light filtering functional layer is 1-5 μm. The display panel further includes a display area and a non-display area. The light filtering functional layer extends from the display area to the non-display area. A distance between a boundary of the light filtering functional layer and a boundary of the display area is 1000-2000 μm.

Optionally, the display area includes a middle area and a peripheral area. The peripheral area is disposed around the middle area. The light filtering functional layer is disposed in the peripheral area and extends to the non-display area. The light-adjusting layers are disposed corresponding to the green light-emitting units and the blue light-emitting units.

Optionally, the sealing layer is formed of an inorganic insulating material. The inorganic insulating material includes at least one of an aluminum oxide ceramic material, a silicon oxide material, and a silicon nitride material. An inner wall of each of the sealing cavities is formed of a polymer polyethylene material.

Optionally, the display panel includes a display area and a non-display area, and the display area includes opening areas and non-opening areas. The red light-emitting units, the green light-emitting units, and the blue light-emitting units are respectively disposed in the opening areas. At least one of the opening areas is within a projection range of each of the sealing cavities on an orthographic projection of the substrate. The display panel further includes a color filter layer. The color filter layer includes black matrices and color filter portions. Each of the black matrices is disposed in a corresponding one of the non-opening areas. The color filter portions are respectively disposed in the opening areas.

The present disclosure provides the display device. The display device includes a driving circuit and the display panel mentioned above. The driving circuit is configured to drive the display panel to display.

In the present disclosure, the light filtering functional layer is disposed inside the display panel, and the sensing structures thereof are configured to sense whether water and oxygen invade the display panel. When water and oxygen invade the display panel, the light transmittance of the light-adjusting layers is controlled to increase, so that the light transmittance of the areas where the green light-emitting units and the blue light-emitting units are located increases, and a brightness of the green light-emitting units and the blue light-emitting units in water and oxygen invasion areas is increased, so as to balance a red-light-displaying phenomenon caused by change in a light transmission wavelength range of an insulating layer of the display panel due to invasion of water and oxygen. The present disclosure mainly improves the brightness of green pixel areas and blue pixel areas, and adopts a compensation method to solve the red-light-displaying phenomenon in water and oxygen invasion areas of the display panel, thereby improving the display quality of the display panel and extending the service life of the display panel.

### BRIEF DESCRIPTION OF DRAWINGS

The drawings are included to provide a further understanding of embodiments of the present disclosure, which form portions of the specification and are used to illustrate implementation manners of the present disclosure and are intended to illustrate operating principles of the present disclosure together with the description. Apparently, the drawings in the following description are merely some of the embodiments of the present disclosure, and those skilled in the art are able to obtain other drawings according to the drawings without contributing any inventive labor.

FIG. 1 is a schematic diagram of a display panel according to a first embodiment of the present disclosure.

FIG. 2 is a top side schematic diagram of the display panel of the present disclosure.

FIG. 3 is a schematic diagram of a light filtering layer according to the first embodiment of the present disclosure.

FIG. 4 is a schematic diagram of the light filtering functional layer according to a second embodiment of the present disclosure.

FIG. 5 is a schematic diagram of the display panel according to the second embodiment of the present disclosure.

FIG. 6 is a schematic diagram of a display device of the present disclosure.

### DETAILED DESCRIPTION

It should be understood that terms, specific structures, and function details disclosed herein are only representative and are used for the purpose of describing exemplary embodiments of the present disclosure. However, the present disclosure may be achieved in many alternative forms and shall not be interpreted to be only limited to the embodiments described herein.

In the description of the present disclosure, terms such as “first” and “second” are only used for the purpose of description, rather than being understood to indicate or imply relative importance or hint the number of indicated technical features. Thus, the feature limited by “first” and “second” may explicitly or implicitly include one or more of the features. include one or more features. In the description of the present disclosure, the meaning of “a plurality of” is two or more unless otherwise specified. In addition, terms such as “upper”, “lower”, “left”, “right”, “vertical”, “horizontal”, etc. indicate direction or position relationships shown based on the drawings, and are only intended to facilitate the description of the present disclosure and the simplification of the description rather than to indicate or imply that the indicated device or element must have a specific direction or be constructed and operated in a specific direction, and therefore, shall not be understood as a limitation to the present disclosure. For those of ordinary skill in the art, the meanings of the above terms in the present disclosure may be understood according to concrete conditions.

The present disclosure is described in detail below with reference to the accompanying drawings and optional embodiments.

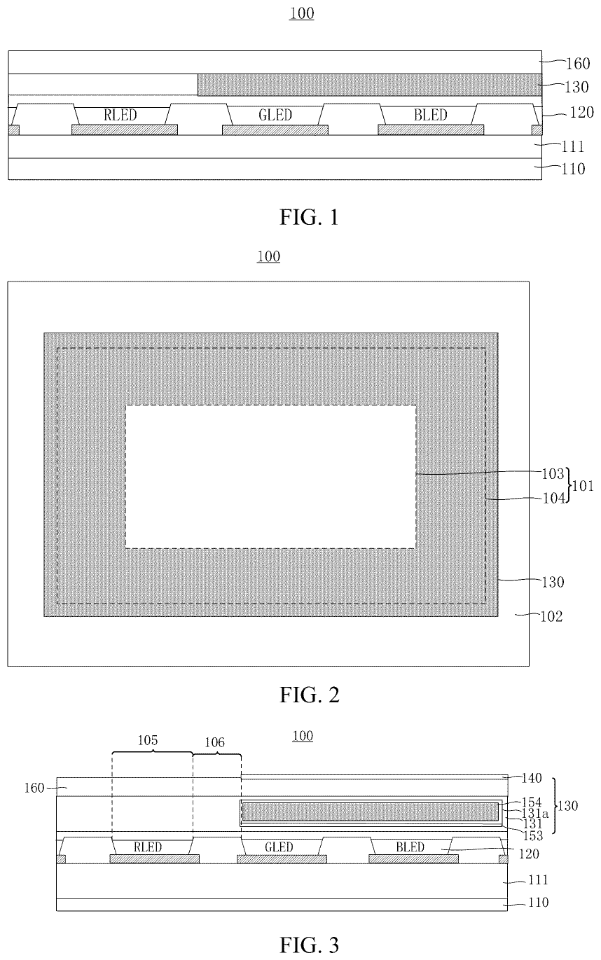

FIG. 1 is a schematic diagram of a display panel according to a first embodiment of the present disclosure. As shown in FIG. 1, the present disclosure provides the display panel 100. The display panel 100 includes a substrate 110, a pixel driving layer 111, a light-emitting unit layer 120, and a light filtering functional layer 130. The pixel driving layer 111 is disposed on the substrate 110. The light-emitting unit layer 120 is disposed on the pixel driving layer 111. The light filtering functional layer 130 is disposed on the light-emitting unit layer 120. The light-emitting unit layer 120 includes red light-emitting units RLED, green light-emitting units GLED, and blue light-emitting units BLED. The light filtering functional layer 130 includes sensing structures 140 and light-adjusting layers 150. The sensing structures 140 are configured to control a light transmittance of the light-adjusting layers 150 disposed on locations of the green light-emitting units GLED and the blue light-emitting units BLED to increase after sensing water and oxygen.

In the present disclosure, the light filtering functional layer 130 is disposed inside the display panel 100, and the sensing structures 140 thereof are configured to sense whether water and oxygen invade the display panel 100. When water and oxygen invade the display panel 100, the light transmittance of the light-adjusting layers 150 is controlled to increase, so that the light transmittance of the areas where the green light-emitting units GLED and the blue light-emitting units BLED are located increases, and a brightness of the green light-emitting units GLED and the blue light-emitting units BLED in water and oxygen invasion areas is increased, so as to balance a red-light-displaying phenomenon caused by change in a light transmission wavelength range of an insulating layer of the display panel 100 due to invasion of water and oxygen. The present disclosure mainly improves the brightness of green pixel areas and blue pixel areas, and adopts a compensation method to solve the red-light-displaying phenomenon in water and oxygen invasion areas of the display panel 100, thereby improving the display quality of the display panel 100 and extending the service life of the display panel 100.

FIG. 2 is a top side schematic diagram of the display panel of the present disclosure. As shown in FIG. 2, the display panel 100 further includes a display area 101 and a non-display area 102. The light filtering functional layer 130 extends from the display area 101 to the non-display area 102, so that the light filtering functional layer 130 is able to cover a junction of the display area 101 and the non-display area 102. Relatively speaking, an edge of the display panel 100, especially an edge of the display area 101, is prone to water and oxygen invasion, which affects the display effect. In the embodiment, by covering the light filtering functional layer 130 at the junction of the display area 101 and the non-display area 102, when water and oxygen enter the display panel 100, display of the edge of the display area 101 is compensated, thereby solving a color cast problem.

It is understood that when water and oxygen invade from an encapsulation layer 160, even if water and oxygen do not enter the light-emitting unit layer 120, water and oxygen may enter an insulating layer formed of silicon nitride or silicon dioxide in the encapsulation layer 160, a light transmission wavelength range of the insulating layer changes. Specifically, a light transmittance of the silicon nitride or a light transmittance of the silicon dioxide to red light increases, resulting in an increase in a proportion of red light in the edge of the display area 101, thereby resulting in the color cast problem. Generally speaking, the encapsulation layer 160 is encapsulated by stacking inorganic layers and organic layers. The inorganic layers and the organic layers are generally formed of the silicon nitride and the silicon dioxide. When there are cracks in the encapsulation layer 160 or when water and oxygen invade between film layer interfaces thereof, areas where water and oxygen invaded are prone to the color cast problem.

Specifically, the display area 101 includes a middle area 103 and a peripheral area 104. The peripheral area 104 is disposed around the middle area 103. The light filtering functional layer 130 is disposed in the peripheral area 104 and extends to the non-display area 102. In the embodiment, the light filtering functional layer 130 is specifically disposed in the peripheral area 104 to achieve color cast compensation for the peripheral area 104. An area of the peripheral area 104 is not greater than an area of the middle area 103.

In one embodiment, only a problem of water and oxygen invasion caused by film rupture in a bending area of the display panel is considered. Therefore, for the display panel 100 that is bent due to folding or rolling, the light filtering functional layer 130 in the present disclosure is only disposed in the folding area of the display panel 100 to achieve color cast compensation in the folding area.

Furthermore, a distance between a boundary of the light filtering functional layer 130 and a boundary of the display area 101 is 1000-2000 μm. The boundary of the light filtering functional layer 130 refers to an edge of the light filtering functional layer 130 disposed in the non-display area 102. Since the non-display area 102 does not participate in the display, the boundary of the peripheral area 104 is fully protected by extending the light filtering functional layer 130 to the non-display area 102 by a certain length.

For the peripheral area 104, in order to change the light transmittance of the light-adjusting layers 150 at the locations of the blue light-emitting units BLED and the green light-emitting units GLED, the light-adjusting layers 150 are connected as a whole layer, and only the light transmittance of part of the light-adjusting layers 150 at the locations of the green light-emitting units GLED and the blue light-emitting units BLED is changed to achieve color cast compensation for the peripheral area 104. It is also possible to configure the light-adjusting layers 150 only at the locations of the green light-emitting units GLED and the blue light-emitting units BLED, so that the light-adjusting layers 150 are disposed corresponding to the green light-emitting units GLED and the blue light-emitting units BLED. After the sensing structures 140 sense water and oxygen, the light-adjusting layers 150 disposed on the locations of the green light-emitting units GLED and the blue light-emitting units BLED are controlled to change the light transmittance.

In a case where the light-adjusting layers 150 are only disposed on the locations of the green light-emitting units GLED and the blue light-emitting units BLED, it is necessary to ensure that when no color cast compensation is performed, the light transmittances of areas where the red light-emitting units RLED, green light-emitting units GLED, and blue light-emitting units BLED are located are consistent. When the sensing structures 140 detect water and oxygen invasion, the light transmittance of the green light-emitting units GLED and the blue light-emitting units BLED is increased to achieve brightness compensation for green light and blue light.

In the pixel arrangement, a red pixel may be disposed separately, and a green pixel and a blue pixel are configured as a group. For example, for a single pixel point composed of the red pixel, the green pixel, and the blue pixel, the green pixel is closer to the blue pixel. Further, in different pixel points, the green pixels thereof are closer to the blue pixels thereof, so that the light-adjusting layers are reasonably configured when the light-adjusting layers 150 cover only the blue pixels and the green pixels.

Specifically, taking a first column of pixel points disposed at an outermost side of the peripheral area 104 as an example, a red pixel column thereof is disposed at an outer side thereof, and a blue pixel column thereof and a green pixel column thereof are disposed at an inner side relative to the red pixel column thereof. In a second column of pixel points, a red pixel column thereof is disposed on an inner side thereof, so that a blue pixel column thereof and a green pixel column thereof in the second column of pixel points are adjacent to the blue pixel column and the green pixel column in the first column of the pixel points. At this time, one of the light-adjusting layers 150 is disposed corresponding to blue pixel columns and green pixel columns of the two columns of the pixel points, while no light-adjusting layer 150 is disposed on the red pixel columns.

FIG. 3 is a schematic diagram of a light filtering layer according to the first embodiment of the present disclosure. As shown in FIG. 3, in the embodiment, the sensing structures 140 include an active metal to detect whether water and oxygen enter the encapsulation layer 160. In the embodiment, the sensing structures 140 are disposed on a periphery of the encapsulation layer 160 and are within the non-display area 102. The light-adjusting layers 150 are disposed in the peripheral area 104 of the display area 101. By configuring the sensing structures 140 on the periphery of the encapsulation layer 160, when water and oxygen enter the periphery of the encapsulation layer 160, the active metal is corroded to cause electrical changes. Therefore, it is determined whether there is water and oxygen invasion by indirect detection. Alternatively, the active metal includes aluminum metal, etc., which is disposed inside the encapsulation layer 160, and electrodes are disposed on an outer side of the encapsulation layer 160 and disposed opposite to the active metal to form capacitors. When an electrical property of internal aluminum electrodes changes, a capacitance changes accordingly. Therefore, it is detected that there are water and oxygen in the encapsulation layer 160.

In the embodiment, the light-adjusting layers 150 have a function of adjusting the light transmittance. The light-adjusting layers 150 are mainly formed by a hydrogel material. The hydrogel material is synthesized by monomers or polymers through forming a water-permeable cross-linked network. The monomers are polymerized to form polymers, and then an interpenetrating polymer network (IPN) is formed through a gel process (cross-linking method). The hydrogel material retains a large amount of water and maintains a three-dimensional network structure. Cross-linking of a condensed network is divided into non-covalent bonds (i.e., physical cross-linking) and covalent bonds (i.e., chemical cross-linking). The hydrogel material is generally a jelly-like solid with elasticity. A polymer hydrogel material is defined as a cross-linked polymer that is able to swell in water and retains a large amount of water but is unable to be dissolved. Forces that induce phase transitions in the polymer hydrogel material are summarized into four categories: hydrophobic interaction, hydrophilic interaction (such as hydrogen bonding and water solvation), van der Waals force, and electrostatic interaction between ions. As an external environment changes, the four forces compete with each other, causing conformations of polymer segments in a solution to change, ultimately leading to phase transition. During a phase transition process, a transmittance of the polymer hydrogel material changes, thereby adjusting the light transmittance.

When macromolecular chains have both hydrophilic groups and hydrophobic groups, conformations of linear polymers in an aqueous solution change as a temperature of the aqueous solution changes. At this time, the linear polymers change from extended random coils to curled globular shapes. The change in the conformations of the linear polymers is generally considered to be a result of competition between the hydrophilic interaction and the hydrophobic interaction. For example, polyacrylamide and polyacrylic acid have thermal expansion temperature sensitivity. Based on their chitosan hydrogel polymers, the polyacrylamide and the polyacrylic acid have different phase transition capabilities at different temperatures by adjusting a composition thereof, and the light transmittance is different at different phase transition degrees.

In the embodiment, the light-adjusting layers 150 are formed by a temperature-sensitive hydrogel material, such as a thermal expansion temperature-sensitive hydrogel.

The light filtering functional layer 130 specifically includes a sealing layer 131. Sealing cavities 131a are defined in the sealing layer 131. A temperature-raising layer 153 and a thermal expansion temperature-sensitive hydrogel layer 154 are disposed in each of the sealing cavities 131a. In each of the sealing cavities 131a, the temperature-raising layer 153 is configured to provide heat for the thermal expansion temperature-sensitive hydrogel layer 154, and the thermal expansion temperature-sensitive hydrogel layer 154 is configured to absorb heat to produce different light transmittances. Each temperature-raising layer 153 is made from a wave-absorbing temperature-raising material to convert ultrasound into heat to cause temperature rise after absorbing the ultrasound. The wave-absorbing temperature-raising material is able to absorb or weaken electromagnetic wave energy projected onto a surface thereof, and is able to convert the electromagnetic wave energy into heat energy or other forms through dielectric loss or magnetic loss of the wave-absorbing temperature-raising material. The wave-absorbing temperature-raising material includes a graphene/vanadium dioxide composite aerogel material or a ceramic wave-absorbing fiber material. The graphene/vanadium dioxide composite aerogel material has a temperature-raising function under the ultrasound, and has different temperature-raising gradients under the ultrasound of different wavelengths. For example, the higher the frequency of the ultrasound, the greater the temperature of the graphene/vanadium dioxide composite aerogel material. Of course, the ultrasound of the same frequency is also allowed to adjust a temperature of each temperature-raising layer 153 to reach a target temperature by adjusting a time parameter. The most representative ceramic wave-absorbing fiber material is silicon carbide (SiC). The SiC has a low absorption frequency band at a frequency of 2-7 GHZ, and has a low absorption degree for the ultrasound. The SiC has a high absorption frequency band at a frequency of 8-18 GHz, and is capable of absorbing up to 90% of the ultrasound. The SiC is rapidly heated to a target temperature by adjusting the wavelength and a time parameter.

The wave-absorbing temperature-raising material needs to absorb external wave sources to generate heat. The frequency, wavelength, and time of the ultrasound affect the temperature rise caused by the wave-absorbing temperature-raising material, so the heat change of each thermal expansion temperature-sensitive hydrogel layer 154 is achieved by adjusting the frequency, the wave intensity, and the time of the ultrasound.

In another embodiment, each of the light-adjusting layers 150 in the present disclosures includes a pH-sensitive hydrogel 152.

Molecular chains of polyacrylic acid (PAA) and polymethacrylic acid (PMAA) include a large amount of ionizable COOH groups, so the PAA and the PMAA are types of intelligent polymer hydrogel material with pH-sensitive properties, which are also called pH-sensitive hydrogel materials. When a pH value of the pH-sensitive hydrogel 152 is greater than a pKa of the PAA (pKa refers to an acidity coefficient or a dissociation constant of a drug, codenamed Ka value, in chemistry and biochemistry, pKa refers to a specific equilibrium constant to represent an ability of an acid to dissociate hydrogen ions), the COOH groups are in a dissociated state. At this time, hydrophilicity of the PAA is enhanced, and a COO-electrostatic repulsion causes the molecular chains of the PAA to exist in conformations of extended random coils, and the system free energy thereof is minimized. When the pH value of the solution is less than the pKa of the PAA, the hydrophilicity of the COOH groups is less than the hydrophilicity of COO—, so the hydrophilicity of the PAA is weakened and the hydrophobicity of the PAA is relatively enhanced. When the pH value of the solution is less than the pKa of PMAA, due to a hydrophobic interaction between backbone carbon chains and side chain methyl groups, the PMAA is in conformations of highly compressed coils. As the pH value of the solution increases, the COOH groups dissociate to obtain negative charges, and the Coulomb electrostatic effect causes the PMAA to be converted into looser extended conformations. Therefore, changing the pH value of the solution may cause a conformational change in acrylic polymer, making the acrylic polymer pH-sensitive. The acrylic polymer has phase transition capabilities at different pH values, and by adjusting a composition thereof, the acrylic polymer may have different phase transition degrees and have different light transmittances.

Each pH-sensitive hydrogel 152 needs to control the pH value thereof to make the light-adjusting layers 150 have different light transmittances. In this regard, the following design is made in the embodiment.

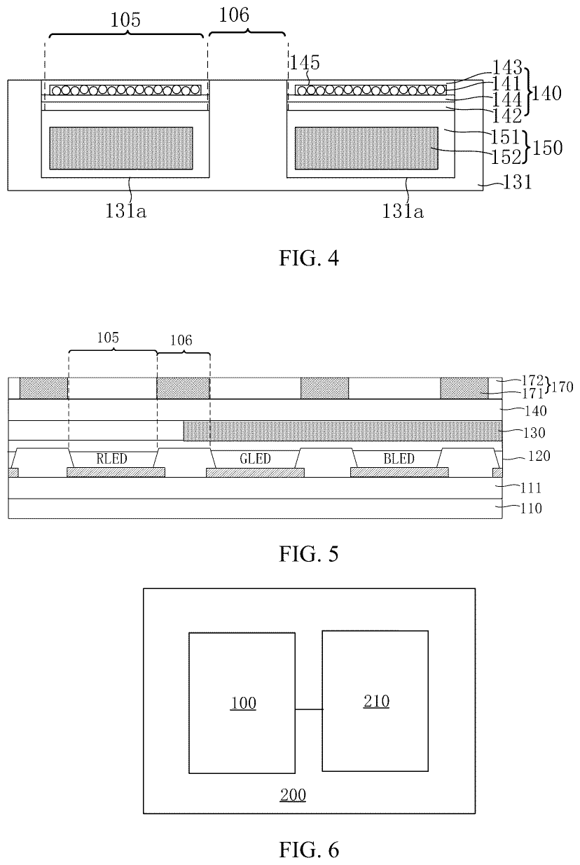

FIG. 4 is a schematic diagram of the light filtering functional layer according to a second embodiment of the present disclosure. As shown in FIG. 4, the light filtering functional layer 130 further includes a sealing layer 131. The sealing layer 131 includes sealing cavities 131a. Each of the sealing cavities 131a includes a corresponding one of the sensing structures 140 and a corresponding one of the light-adjusting layers 150. It is understood that each of the sealing cavities 131a is disposed corresponding to at least one of the blue light-emitting units BLED or at least one of the green light-emitting units GLED. For instance, each of the sealing cavities 131a is disposed corresponding to a corresponding one of the blue light-emitting units BLED or a corresponding one of the green light-emitting units GLED. Alternatively, each of the sealing cavities 131a is disposed corresponding to corresponding blue light-emitting units BLED or corresponding green light-emitting units GLED.

The sensing structures 140 are configured to sense water and oxygen in the sealing layer 131. Each of the sensing structures 140 is disposed on one side of a corresponding one of the light-adjusting layers 150 away from the light-emitting unit layer 120. Specifically, each of the sealing cavities 131a is disposed corresponding to at least one of the opening areas 105.

The present disclosure seals the sensing structures 140 and the light-adjusting layers 150 are disposed in the sealing cavities 131a through the sealing layer 131. The sealing layer 131 may not be disposed on one side of each of the sealing cavities 131a where the corresponding one of the sensing structures 140 is disposed, or a thinner sealing layer 131 is disposed. Therefore, when water and oxygen invade the encapsulation layer 160 and water and oxygen enter the sensing structures 140, each of the sensing structures 140 adjusts the transmittance of the corresponding one of the light-adjusting layers 150 by adjusting the pH value of the pH-sensitive hydrogel 152 thereof.

Specifically, each of the sensing structures 140 includes an alkaline metal 141 and an anion exchange membrane 142, the anion exchange membrane 142 thereof is configured to isolate the alkaline metal 141 thereof and the corresponding one of the light-adjusting layers 150, and the alkaline metal 141 thereof is configured to absorb water and oxygen and then release alkaline anions to enter a corresponding acidic solution 151 through the anion exchange membrane 142 thereof, so as to improve the pH value of the corresponding acidic solution 151. In each of the sensing structures 140, the alkaline metal 141 refers to a metal capable of generating an alkaline solution after reacting with water and oxygen, and the pH value of the alkaline solution is greater than 7. It is understood that the sealing layer 131 of the embodiment is disposed on the light-emitting unit layer, and is disposed inside the encapsulation layer 160 or disposed below the encapsulation layer 160.

In the embodiment, when water and oxygen invade the encapsulation layer 160, each of the sensing structures 140 contacts water and oxygen, and the alkaline metal 141 thereof reacts with water and oxygen to generate alkaline anions. The anion exchange membrane 142 thereof only allows anions to pass through and has a small pore size, allowing only OH— ions to pass through, and anions greater than OH— are unable to pass through. When the OH— ions enter a corresponding pH-sensitive hydrogel 152, the OH— ions neutralize H+ ions, thereby increasing the pH value, so that the light transmittance of the corresponding pH-sensitive hydrogel 152 increases.

Specifically, each of the light-adjusting layers 150 includes an acidic solution 151 and the pH-sensitive hydrogel 152. The pH-sensitive hydrogel 152 is in the acidic solution 151, and when the pH value of the acidic solution 151 thereof increases, a light transmittance of the pH-sensitive hydrogel thereof increases accordingly. In the embodiment, in each of the light-adjusting layers 150, the pH-sensitive hydrogel 152 thereof is disposed in the acidic solution 151 thereof, so that the pH-sensitive hydrogel 152 thereof has an initial light transmittance. Specifically, the light transmittance of the pH-sensitive hydrogel 152 thereof in the acidic solution 151 thereof is 0%-10%. In each of the light-adjusting layers 150, when the OH— ions in the acidic solution 151 thereof gradually increase, the light transmittance of the pH-sensitive hydrogel 152 thereof is able to increase from 10% to 100%.

The sealing layer 131 is formed of an inorganic insulating material. The inorganic insulating material includes at least one of an aluminum oxide ceramic material, a silicon oxide material, and a silicon nitride material. An inner wall of each of the sealing cavities 131a is formed of a polymer polyethylene material.

The sealing layer 131 in the embodiment mainly plays a sealing role to prevent each acidic solution 151 disposed inside and each pH-sensitive hydrogel 152 from leaking. Of course, in general, a weight of each acidic solution 151 and each pH-sensitive hydrogel 152 disposed inside the sealing layer 131 is relatively small, and the sealing layer 131 of a certain thickness is able to seal them. A thickness of the light filtering functional layer 130 is 1-5 μm.

Since each alkaline metal 141 has a reaction product after reacting with water and oxygen, a reaction chamber 145 is provided in each of the sealing cavities 131a. Specifically, each of the sensing structures 140 further includes a gas filter membrane 143 and a liquid filter membrane 144. The reaction chamber 145 is formed between the gas filter membrane 143 thereof and the liquid filter membrane thereof 144. In each of the sealing cavities 131a, the alkaline metal 141 thereof is disposed in the reaction chamber 145 thereof, the gas filter membrane 143 thereof is disposed on one side of the liquid filter membrane 144 thereof away from the corresponding one of the light-adjusting layers 150, and the liquid filter membrane 144 thereof is disposed between the reaction chamber 145 thereof and the anion exchange membrane 142 thereof.

In the embodiment, each gas filter membrane 143 allows water vapor and oxygen to pass through, and each liquid filter membrane 144 allows liquid to pass through. In each of the sealing cavities 131a, after the alkaline metal 141 thereof in the reaction chamber 145 thereof reacts with water and oxygen, taking metallic sodium as an example, the metallic sodium reacts with water and oxygen to produce the sodium hydroxide alkaline solution, and the sodium hydroxide alkaline solution passes through the liquid filter membrane 144 thereof, then the OH— ions thereof are released into the acidic solution 151 thereof through the anion exchange membrane 142 thereof. Further, in each of the sealing cavities 131a, the anion exchange membrane 142 thereof isolates the reaction chamber 145 thereof from the acidic solution 151 thereof. Moreover, in each of the sealing cavities 131a, the alkaline metal 141 thereof includes the metallic sodium, and the metallic sodium absorbs water and oxygen to form the sodium hydroxide solution, and the sodium hydroxide solution releases the hydroxide ions into the acidic solution 151 thereof.

In the embodiment, the sealing layer 131, the alkaline metal 141 and the anion exchange membrane 142 of each of the sensing structures, and the pH-sensitive hydrogel 152 of each of the light-adjusting layers 150 are provided. Through the above structures, when the encapsulation layer 160 disposed on an outer peripheral of the display panel fails and water and oxygen enter the sensing structures 140, the metallic sodium thereof absorbs water and oxygen and reacts to produce the NaOH alkaline solution. After the NaOH alkaline solution passes through the liquid filter membrane 144/anion exchange membrane 142 thereof, the OH— ions enter the acidic solution 151 of the pH-sensitive hydrogel 152. The pH value of the acidic solution 151 thereof changes with continuous entry of the OH— ions, and the pH-sensitive hydrogel 152 thereof completes different degrees of phase transition in solutions with different pH values. It is worth mentioning that in each of the sealing cavities 131a, when the OH— ions enter the acidic solution 151 thereof to increase the pH value of the acidic solution 151 thereof, if there is no more water and oxygen invasion, the pH value of the acidic solution 151 thereof is stable, and the corresponding one of the light-adjusting layers 150 has a fixed light transmittance. When water and oxygen invade again, the light transmittance of the corresponding one of the light-adjusting layers 150 continues to increase until the light transmittance reaches a threshold value.

When the display screen does not have any encapsulation failure and displays normally, an initial light transmittance of each pH-sensitive hydrogel 152 is 0-10%, which is determined by the material's characteristics and the pH value of each acidic solution 151. In this case, the edge of the display screen is displayed uniformly.

When the encapsulation fails and water vapor enters the edge of the display screen, the pH value of the acidic solution 151 in a corresponding one of the sealing cavities 131a changes, and the pH-sensitive hydrogel 152 thereof at a corresponding position undergoes a corresponding degree of phase transition, so that the light transmittance at the corresponding position is adjusted accordingly, and corresponding green pixels and blue pixels are compensated for brightness to reduce the red-light-displaying phenomenon at the edge of the display screen, thereby realizing the uniformity of overall brightness of the display screen. Since the change in the pH value of the acidic solution in the corresponding one of the sealing cavities is directly related to the amount of water vapor entering, the amount of water vapor and the influence of corresponding membranes are reversely determined. After a color point offset is determined, a brightness compensation amount of the corresponding green pixels and blue pixels is determined, and then a required light transmittance is calculated. The light transmittance is related to the pH value of the corresponding acidic solution 151, and the pH value of the corresponding acidic solution 151 is determined by the amount of water vapor entering, so there is a direct relationship between the pH value and the light transmittance. A size of an area that needs to be compensated and the coefficient relationship between the pH value and the light transmittance are directly determined based on the direct relationship.

FIG. 5 is a schematic diagram of the display panel according to the second embodiment of the present disclosure. As shown in FIG. 5, the display panel 100 includes a display area 101 and a non-display area 102, and the display area 101 includes opening areas 105 and non-opening areas 106. The red light-emitting units RLED, the green light-emitting units GLED, and the blue light-emitting units BLED are respectively disposed in the opening areas 105. The display panel 100 further includes a color filter layer 170. The color filter layer 170 includes black matrices 171 and color filter portions 172. Each of the black matrices 171 is disposed in a corresponding one of the non-opening areas 106. The color filter portions 172 are respectively disposed in the opening areas 105. The display panel of the embodiment is applied to a Color film on Encapsulation (COE) display panel 100. The COE is a new technology to replace polarizers. A light transmittance of a color filter is capable of reaching up to 60%, which greatly increases the light brightness, thereby reducing power consumption of an OLED display device and increasing the service life.

At least one of the opening areas 105 is within a projection range of each of the sealing cavities 131a on an orthographic projection of the substrate 110. For instance, each of the sealing cavities 131a is corresponding to a plurality of opening areas 105. The corresponding blue light-emitting units BLED and the corresponding green light-emitting units GLED are respectively disposed at the plurality of opening areas 105. For instance, each of the sealing cavities 131a is corresponding to the corresponding one of the opening areas 105, and the corresponding blue light-emitting units BLED or the corresponding green light-emitting units GLED are disposed in the corresponding one of the opening areas 105.

FIG. 6 is a schematic diagram of a display device of the present disclosure. As shown in FIG. 6, the present disclosure provides a display device. The display device 200 includes a driving circuit 210 and the display panel 100 mentioned above. The driving circuit 210 is configured to drive the display panel 100 to display.

The present disclosure provides the light filtering functional layer 130 inside the display panel 100, and the sensing structures 140 are disposed to sense whether there is water and oxygen invasion. When there is water and oxygen invasion, the light transmittance of each of the light-adjusting layers 150 is controlled to increase, so that the light transmittance of the areas where the green light-emitting units GLED and the blue light-emitting units BLED are located increases, and the brightness of the green light-emitting units GLED and the blue light-emitting units BLED in water and oxygen invasion areas is increased to balance the red-light-displaying phenomenon caused by the change in the wavelength range of the light transmission of the insulating layer due to water and oxygen invasion. The present disclosure mainly improves the brightness of the green pixel areas and the blue pixel areas, and adopts a compensation method to solve the red-light-displaying phenomenon in water and oxygen invasion areas of the display panel 100, thereby improving the display quality of the display panel 100 and extending the service life of the display panel 100.

It should be noted that the concept of the present disclosure can form a large number of embodiments, but a length of the document is limited and it is impossible to list them one by one. Therefore, under the premise of no conflict, the embodiments or technical features described above can be arbitrarily combined to form new embodiments. After the embodiments or technical features are combined, the original technical effects are enhanced.

The above content is a further detailed description of the present disclosure in combination with specific optional implementation methods, and it cannot be determined that the specific implementation of the present disclosure is limited to these descriptions. For those skilled in the art, several simple deductions or substitutions can be made without departing from the concept of the present disclosure, which should be regarded as falling within the protection scope of the present disclosure.

What is claimed is:

1. A display panel, comprising:
a substrate;
a pixel driving layer disposed on the substrate;
a light-emitting unit layer disposed on the pixel driving layer; and
a light filtering functional layer disposed on the light-emitting unit layer;
wherein the light-emitting unit layer comprises red light-emitting units, green light-emitting units, and blue light-emitting units, the light filtering functional layer comprises sensing structures and light-adjusting layers, and the sensing structures are configured to control a light transmittance of the light-adjusting layers disposed on locations of the green light-emitting units and the blue light-emitting units to increase after sensing water and oxygen.

2. The display panel according to claim 1, wherein the light filtering functional layer further comprises a sealing layer, the sealing layer comprises sealing cavities, and each of the sealing cavities comprises a corresponding one of the sensing structures and a corresponding one of the light-adjusting layers, and the sensing structures are configured to sense water and oxygen in the sealing layer;
wherein each of the sensing structures is disposed on one side of a corresponding one of the light-adjusting layers away from the light-emitting unit layer.

3. The display panel according to claim 2, wherein each of the light-adjusting layers comprises an acidic solution and a pH-sensitive hydrogel, the pH-sensitive hydrogel thereof is in the acidic solution thereof, and when a pH value of the acidic solution thereof increases, a light transmittance of the pH-sensitive hydrogel thereof increases accordingly;
wherein each of the sensing structures comprises an alkaline metal and an anion exchange membrane, the anion exchange membrane thereof is configured to isolate the alkaline metal thereof and the corresponding one of the light-adjusting layers, and the alkaline metal thereof is configured to absorb water and oxygen and then release alkaline anions to enter a corresponding acidic solution through the anion exchange membrane thereof, so as to improve the pH value of the corresponding acidic solution.

4. The display panel according to claim 3, wherein each of the sensing structures further comprises a gas filter membrane and a liquid filter membrane, a reaction chamber is formed between the gas filter membrane thereof and the liquid filter membrane thereof, the alkaline metal thereof is disposed in the reaction chamber thereof, the gas filter membrane thereof is disposed on one side of the liquid filter membrane thereof away from the corresponding one of the light-adjusting layers, and the liquid filter membrane thereof is disposed between the reaction chamber thereof and the anion exchange membrane thereof.

5. The display panel according to claim 3, wherein in each of the light-adjusting layers, the alkaline metal thereof comprises metallic sodium, the metallic sodium absorbs water and oxygen to form a sodium hydroxide solution, and the sodium hydroxide solution releases hydroxide ions into the acidic solution.

6. The display panel according to claim 1, wherein a thickness of the light filtering functional layer is 1-5 μm;
wherein the display panel further comprises a display area and a non-display area, the light filtering functional layer extends from the display area to the non-display area, and a distance between a boundary of the light filtering functional layer and a boundary of the display area is 1000-2000 μm.

7. The display panel according to claim 6, wherein the display area comprises a middle area and a peripheral area, the peripheral area is disposed around the middle area, and the light filtering functional layer is disposed in the peripheral area and extends to the non-display area;
wherein the light-adjusting layers are disposed corresponding to the green light-emitting units and the blue light-emitting units.

8. The display panel according to claim 2, wherein the sealing layer is formed of an inorganic insulating material, the inorganic insulating material comprises at least one of an aluminum oxide ceramic material, a silicon oxide material, and a silicon nitride material, and an inner wall of each of the sealing cavities is formed of a polymer polyethylene material.

9. The display panel according to claim 2, wherein the display panel comprises a display area and a non-display area, and the display area comprises opening areas and non-opening areas;
wherein the red light-emitting units, the green light-emitting units, and the blue light-emitting units are respectively disposed in the opening areas, and at least one of the opening areas is within a projection range of each of the sealing cavities on an orthographic projection of the substrate;
wherein the display panel further comprises a color filter layer, the color filter layer comprises black matrices and color filter portions, each of the black matrices is disposed in a corresponding one of the non-opening areas, and the color filter portions are respectively disposed in the opening areas.

10. The display panel according to claim 2, wherein each of the sealing cavities is disposed corresponding to a corresponding one of the blue light-emitting units or a corresponding one of the green light-emitting units.

11. The display panel according to claim 2, wherein each of the sealing cavities is disposed corresponding to corresponding blue light-emitting units or corresponding green light-emitting units.

12. The display panel according to claim 2, wherein the display panel comprises opening areas, at least one of the opening areas is within in a projection range of each of the sealing cavities on an orthographic projection of the substrate.

13. A display device, comprising:
a display panel; and
a driving circuit configured to drive the display panel to display;
wherein the display panel comprises:
a substrate;
a pixel driving layer disposed on the substrate;
a light-emitting unit layer disposed on the pixel driving layer; and
a light filtering functional layer disposed on the light-emitting unit layer;
wherein the light-emitting unit layer comprises red light-emitting units, green light-emitting units, and blue light-emitting units, the light filtering functional layer comprises sensing structures and light-adjusting layers, and the sensing structures are configured to control a light transmittance of the light-adjusting layers disposed on locations of the green light-emitting units and the blue light-emitting units to increase after sensing water and oxygen.

14. The display device according to claim 13, wherein the light filtering functional layer further comprises a sealing layer, the sealing layer comprises sealing cavities, and each of the sealing cavities comprises a corresponding one of the sensing structures and a corresponding one of the light-adjusting layers, and the sensing structures are configured to sense water and oxygen in the sealing layer;
wherein each of the sensing structures is disposed on one side of a corresponding one of the light-adjusting layers away from the light-emitting unit layer.

15. The display device according to claim 14, wherein each of the light-adjusting layers comprises an acidic solution and a pH-sensitive hydrogel, the pH-sensitive hydrogel thereof is in the acidic solution thereof, and when a pH value of the acidic solution thereof increases, a light transmittance of the pH-sensitive hydrogel thereof increases accordingly;
wherein each of the sensing structures comprises an alkaline metal and an anion exchange membrane, the anion exchange membrane thereof is configured to isolate the alkaline metal thereof and the corresponding one of the light-adjusting layers, and the alkaline metal thereof is configured to absorb water and oxygen and then release alkaline anions to enter a corresponding acidic solution through the anion exchange membrane thereof, so as to improve the pH value of the corresponding acidic solution.

16. The display device according to claim 15, wherein each of the sensing structures further comprises a gas filter membrane and a liquid filter membrane, a reaction chamber is formed between the gas filter membrane thereof and the liquid filter membrane thereof, the alkaline metal thereof is disposed in the reaction chamber thereof, the gas filter membrane thereof is disposed on one side of the liquid filter membrane thereof away from the corresponding one of the light-adjusting layers, and the liquid filter membrane thereof is disposed between the reaction chamber thereof and the anion exchange membrane thereof.

17. The display device according to claim 15, wherein in each of the light-adjusting layers, the alkaline metal thereof comprises metallic sodium, the metallic sodium absorbs water and oxygen to form a sodium hydroxide solution, and the sodium hydroxide solution releases hydroxide ions into the acidic solution.

18. The display device according to claim 14, wherein a thickness of the light filtering functional layer is 1-5 μm;
wherein the display panel further comprises a display area and a non-display area, the light filtering functional layer extends from the display area to the non-display area, and a distance between a boundary of the light filtering functional layer and a boundary of the display area is 1000-2000 μm.
